(19) United States
(12) Patent Application Publication
(10) Pub. No.: US 2026/0136558 A1
(43) Pub. Date: May 14, 2026

(54) SEMICONDUCTOR MEMORY DEVICE AND ELECTRONIC SYSTEM INCLUDING SAME

(71) Applicant: Samsung Electronics Co., Ltd., Suwon-si (KR)

(72) Inventors: Sangjae LEE, Suwon-si (KR); Youngrok KIM, Suwon-si (KR); Ye-Ro LEE, Suwon-si (KR)

(73) Assignee: Samsung Electronics Co., Ltd., Suwon-si (KR)

(21) Appl. No.: 19/350,451

(22) Filed: Oct. 6, 2025

(30) Foreign Application Priority Data
Nov. 14, 2024 (KR) 10-2024-0161670

(51) Int. Cl. H10B 43/40; H01L 23/00; H01L 25/065; H01L 25/18; H10B 41/27; H10B 41/35; H10B 41/41; H10B 43/27; H10B 43/35; H10B 80/00

(52) U.S. Cl. CPC H10B 43/40; H10B 41/27; H10B 41/35; H10B 41/41; H10B 43/27; H10B 43/35; H10B 80/00; H10W 90/00; H10W 90/792

(57) ABSTRACT

A semiconductor memory device may include a cell structure, and a peripheral circuit structure on the cell structure. The peripheral circuit structure comprises a peripheral circuit substrate comprising a first surface, a second surface opposite to the first surface, and a protrusion protruding from the second surface, a peripheral circuit transistor on the first surface, a liner layer extending along the second surface, and the liner layer on an upper surface and side surfaces of the protrusion, a peripheral circuit insulating film on the liner layer, a first pad on the peripheral circuit insulating film, and a pad contact in the peripheral circuit insulating film and connected to the first pad.

### CROSS-REFERENCE TO RELATED APPLICATIONS

This application claims priority to Korean Patent Application No. 10-2024-0161670, filed in the Korean Intellectual Property Office on Nov. 14, 2024, the entire contents of which are hereby incorporated by reference.

### BACKGROUND

Example embodiments of the present disclosure relate to a semiconductor memory device and an electronic system including the same.

There is a desire for semiconductor memory devices capable of storing high-capacity data in electronic systems that requires data storage. Accordingly, research is being conducted to increase the data storage capacity of semiconductor memory devices. For example, a semiconductor device including one or more methods for increasing the data storage capacity of the semiconductor device, including a three-dimensional arrangement of memory cells instead of a two-dimensional arrangement.

### SUMMARY

Some example embodiments of the present disclosure provide a semiconductor memory device with improved electrical characteristics and/or reliability.

Some example embodiments of the present disclosure may also provide an electronic system with improved electrical characteristics and/or reliability.

According to some example embodiments of the present disclosure, by forming the liner layer on the peripheral circuit substrate of the semiconductor memory device, heat generated by the peripheral circuit transistor may be conducted to the pad along the liner layer with a relatively high thermal conductivity and dissipated outside of the device.

According to some example embodiments of the present disclosure, by increasing the width of the bottom surface of the trench formed in the peripheral circuit structure of the semiconductor memory device, when exposed, the area of the pad may be increased. As described above, as the upper surface and a portion of the side surface of the pad are exposed by the trench, there may be an increase of heat dissipated from the pad outside of the device.

According to some example embodiments of the present disclosure, a semiconductor memory device may include a cell structure, and a peripheral circuit structure on the cell structure. The peripheral circuit structure comprises a peripheral circuit substrate comprising a first surface, a second surface opposite to the first surface, and a protrusion protruding from the second surface, a peripheral circuit transistor on the first surface, a liner layer extending along the second surface, and the liner layer on an upper surface and side surfaces of the protrusion, a peripheral circuit insulating film on the liner layer, a first pad on the peripheral circuit insulating film, and a pad contact in the peripheral circuit insulating film and connected to the first pad.

According to some example embodiments of the present disclosure, a semiconductor memory device may include a channel structure, a cell interlayer insulating film covering the channel structure, a cell structure comprising a first bonding pad on the cell interlayer insulating film, and a peripheral circuit structure on the cell structure. The peripheral circuit structure comprises a peripheral circuit substrate comprising a first surface and a second surface opposite to the first surface, a peripheral circuit transistor on the first surface, a second bonding pad between the peripheral circuit substrate and the cell structure, the second bonding pad coupled to the first bonding pad, a liner layer on the second surface, a peripheral circuit insulating film on the liner layer, a first pad on the peripheral circuit insulating film, a pad contact in the peripheral circuit insulating film and connected to the first pad, and a first trench on an upper surface of the peripheral circuit insulating film, the first trench exposing at least a portion of the first pad.

According to some example embodiments of the present disclosure, a semiconductor memory device may include a main substrate, a semiconductor memory device comprising a cell structure on the main substrate and a peripheral circuit structure stacked on the cell structure, and a controller on the main substrate and electrically connected to the semiconductor memory device. The cell structure comprises a cell substrate, a plurality of gate electrodes stacked to be spaced apart from each other on the cell substrate, a channel structure penetrating the plurality of gate electrodes, and a first bonding pad on the channel structure. The peripheral circuit structure comprises, a peripheral circuit substrate comprising a first surface, a second surface opposite to the first surface, and a protrusion protruding from the second surface, a peripheral circuit transistor on the first surface, a second bonding pad between the peripheral circuit transistor and the channel structure, the second bonding pad coupled to the first bonding pad, a liner layer extending along the second surface and an upper surface and side surfaces of the protrusion, a peripheral circuit insulating film on the liner layer, a pad on the peripheral circuit insulating film, a pad contact in the peripheral circuit insulating film and connected to the pad, and a trench on an upper surface of the peripheral circuit insulating film and exposing an upper surface and at least a portion of a side surface of the pad.

According to some example embodiments of the present disclosure, a method of manufacturing a semiconductor memory device includes forming a cell structure on a first substrate, forming a peripheral circuit structure on a second substrate, the peripheral circuit structure including a first surface exposing the first surface of the second substrate and an upper surface of a first portion of a peripheral circuit insulating film surrounding the second substrate, and a second surface opposite the first surface, bonding the cell structure to second surface of the peripheral circuit structure, forming a first mask pattern on the first surface of the peripheral circuit structure, the first mask pattern exposing a portion of the first surface of the peripheral circuit structure, etching the second substrate using the first mask pattern as an etching mask to form a protrusion, removing all portions of the first mask pattern still remaining, forming a liner layer on the first surface of the peripheral circuit structure and the peripheral circuit insulating film, forming a second portion of the peripheral circuit insulating film on the liner layer, planarizing the second portion of the peripheral circuit insulating film such that an upper surface of the second portion of the peripheral circuit insulating film is coplanar with an upper surface of the liner layer forming a second mask pattern on the second portion of the peripheral circuit insulating film and a portion of the liner layer, etching the second mask pattern, an exposed portion of the liner layer, and the first portion of the peripheral circuit insulating film, removing all portions of the second mask pattern still remaining, forming a third portion of the peripheral circuit insulating film on the first portion of the peripheral circuit insulating film, the second portion of the peripheral circuit insulating film and an exposed upper surface of the liner layer, forming a third mask pattern on the peripheral circuit insulating film, etching the peripheral circuit insulating film and a portion of the upper surface of the liner layer to form a contact hole, removing all portions of the third mask pattern still remaining, forming a pad contact in the contact hole, forming a through via in the peripheral circuit insulating film, forming a first pad on the pad contact, and a second pad on the through via, forming a fourth portion of the peripheral circuit insulating film on an exposed upper surface of the peripheral circuit insulating film, the first pad, and the second pad, forming a first upper insulating film on the peripheral circuit insulating film, forming a first trench in the peripheral circuit insulating film exposing an upper surface of the first pad, and a second trench in the peripheral circuit insulating film exposing an upper surface of the second pad, removing a portion of the peripheral circuit insulating film to expose a portion of side surfaces of the first pad and side surfaces of the second pad.

According to some example embodiments of the present disclosure, the removing the portion of the peripheral circuit insulating film is performed by a wet etching process.

### BRIEF DESCRIPTION OF THE DRAWINGS

The above and other embodiments and features of the present disclosure will become more apparent by describing in detail some example embodiments thereof with reference to the attached drawings, in which:

FIG. 1 is a schematic exploded perspective view provided to explain a semiconductor memory device according to some example embodiments;

FIG. 2 is a cross-sectional view provided to explain a semiconductor memory device according to some example embodiments;

FIG. 3 is an enlarged view provided to explain a region Q1 of FIG. 2;

FIG. 4 is an enlarged view provided to explain a region Q2 of FIG. 2;

FIG. 5 is a diagram provided to explain a semiconductor memory device according to some example embodiments;

FIG. 6 is a diagram provided to explain a semiconductor memory device according to some example embodiments;

FIGS. 7 and 8 are diagrams provided to explain a semiconductor memory device according to some example embodiments;

FIG. 9 is a diagram provided to explain a semiconductor memory device according to some example embodiments;

FIG. 10 is a diagram provided to explain a semiconductor memory device according to some example embodiments;

FIG. 11 is a schematic exploded perspective view provided to explain a semiconductor memory device according to some example embodiments;

FIG. 12 is a diagram provided to explain a semiconductor memory device according to some example embodiments;

FIGS. 13 to 25 are diagrams showing intermediate stages, provided to explain a method for manufacturing a semiconductor memory device according to some example embodiments;

FIG. 26 is an example block diagram provided to explain an electronic system according to some example embodiments;

FIG. 27 is an example perspective view provided to explain an electronic system according to some example embodiments; and

FIG. 28 is a schematic cross-sectional view taken along line V-V of FIG. 27.

### DETAILED DESCRIPTION

In the present disclosure, terms such as first, second, etc. may be used to describe various devices or components, but the devices or components are not limited by these terms. It should be understood that these terms are only used to distinguish one element or component from another element or component. It goes without saying that the first element or component mentioned below may be the second element or component within the technical idea of the present disclosure.

A semiconductor memory device and an electronic system including the semiconductor memory device according to some example embodiments will be described in detail with reference to the drawings.

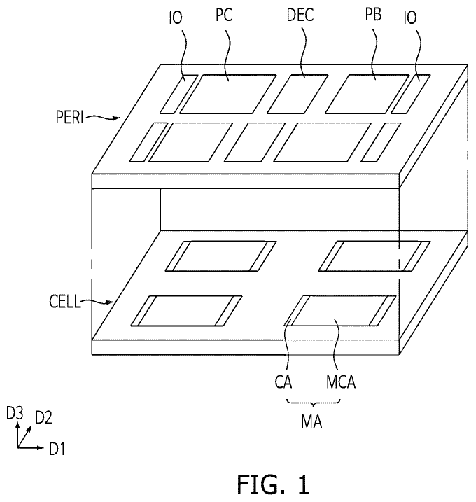

FIG. 1 is a schematic exploded perspective view provided to explain a semiconductor memory device according to some example embodiments.

Referring to FIG. 1, the semiconductor memory device according to some example embodiments may include a cell structure CELL and a peripheral circuit structure PERI.

The peripheral circuit structure PERI may be stacked on the cell structure CELL in a third direction D3. The peripheral circuit structure PERI may be disposed on the cell structure CELL. For example, each of the peripheral circuit structure PERI and the cell structure CELL may be bonded together using a bonding pad.

The cell structure CELL may include a cell array area MCA and a connection area CA. The connection area CA may be disposed on at least one side of the cell array area MCA. A plurality of memory areas MA including the cell array area MCA and the connection area CA may be disposed.

The peripheral circuit structure PERI may include a row decoder DEC, a page buffer PB, other peripheral circuits PC, and a data input/output circuit IO. In the peripheral circuit structure PERI, the row decoder DEC may decode an input address to generate driving signals of the word line and transmit the same. The page buffer PB may be connected to the cell array area MCA through bit lines to read information stored in the memory cells. The other peripheral circuits PC may refer to an area including a control logic and a voltage generator, and may include, for example, a latch circuit, a cache circuit, and/or a sense amplifier.

In some example embodiments, the data input/output circuit IO may be connected to a heat dissipation pad part. The heat dissipation pad part may discharge heat generated from the data input/output circuit IO outside of the device. Various circuit areas (e.g., the row decoder DEC, the page buffer PB, the other peripheral circuits PC, and the data input/output circuit IO) in the peripheral circuit structure PERI may be arranged in various forms.

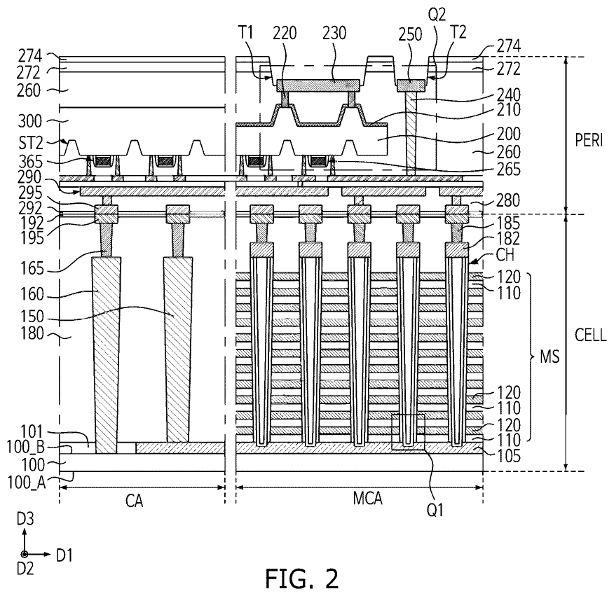

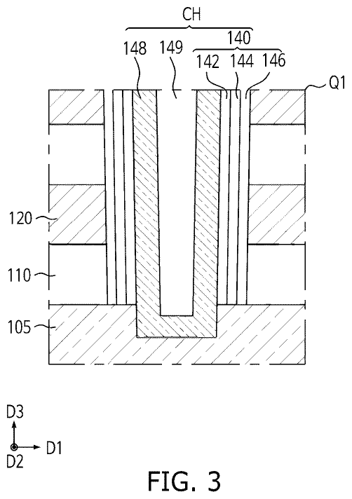

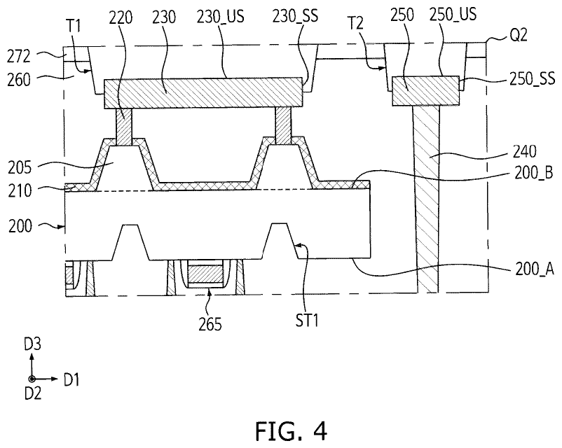

FIG. 2 is a cross-sectional view provided to explain a semiconductor memory device according to some example embodiments. FIG. 3 is an enlarged view provided to explain a region Q1 of FIG. 2. FIG. 4 is an enlarged view provided to explain a region Q2 of FIG. 2. For reference, FIG. 2 may be an example cross-sectional view taken along a first direction D1, illustrating a portion of the cell array area MCA and a portion of the connection area CA of the semiconductor memory device of FIG. 1.

Referring to FIGS. 2 to 4, the semiconductor memory device according to some example embodiments may include a cell structure CELL and a peripheral circuit structure PERI.

The cell structure CELL may include a cell substrate 100, an insulating substrate 101, a common source plate 105, a mold structure MS, a channel structure CH, a first connection via 150, a second connection via 160, a cell interlayer insulating film 180, a channel pad 182, a channel contact 185, a first bonding insulating layer 192, a first bonding pad 195, etc.

For example, the cell substrate 100 may include a semiconductor substrate such as a silicon substrate, a germanium substrate, or a silicon-germanium substrate. Alternatively, the cell substrate 100 may include a silicon-on-insulator (SOI) substrate, a germanium-on-insulator (GOI) substrate, etc. In some example embodiments, the cell substrate 100 may include polysilicon (poly Si). However, example embodiments are not limited thereto.

The cell substrate 100 may include a first surface 100_A and a second surface 100_B opposite to the first surface 100_A. The second surface 100_B of the cell substrate 100 may refer to a surface on which the mold structure MS and the channel structure CH are disposed. The first surface 100_A of the cell substrate 100 may be referred to as a back side of the cell substrate 100. The second surface 100_B of the cell substrate 100 may be referred to as a front side of the cell substrate 100.

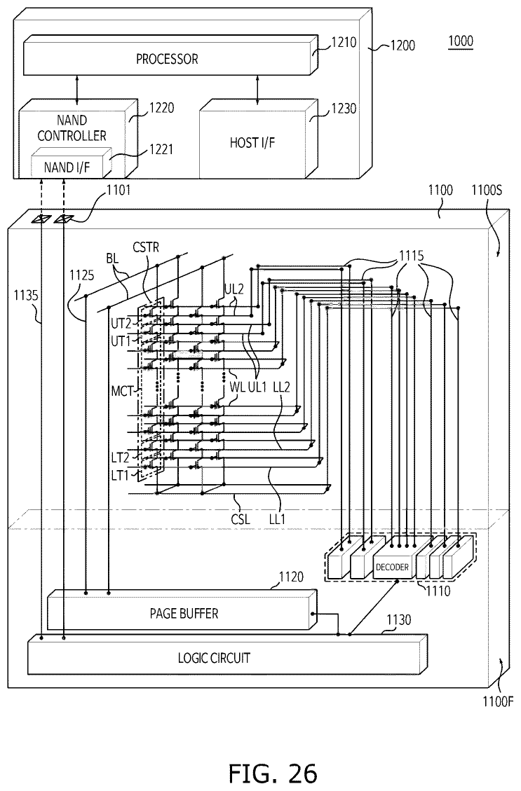

The common source plate 105 may be disposed on the second surface 100_B of the cell substrate 100. The common source plate 105 may be disposed on the cell array area MCA. In some example embodiments, a portion of the common source plate 105 may extend to the extension area CA. The common source plate 105 may be connected to the channel structure CH. For example, the common source plate 105 may be electrically connected to a semiconductor pattern 148 of the channel structure CH. The common source plate 105 may be connected to the second connection via 160 in the connection area CA. The common source plate 105 may be provided as a common source line (e.g., CSL of FIG. 26) of the semiconductor memory device. For example, the common source plate 105 may include polycrystalline silicon or metal doped with an impurity, but example embodiments are not limited thereto.

The mold structure MS may be disposed on the common source plate 105. The mold structure MS may be disposed on the cell array area CA of the cell substrate 100. The mold structure MS may include a plurality of mold insulating layers 110 and a plurality of gate electrodes 120 alternately stacked in the third direction D3. Each of the mold insulating layers 110 and each of the gate electrodes 120 may have a layered structure extending parallel to the second surface 100_B of the cell substrate 100. The gate electrodes 120 may be sequentially stacked on the common source plate 105 and spaced apart from each other by the mold insulating layers 110.

In some example embodiments, some of the plurality of gate electrodes 120 may be provided as a ground select line GSL of the semiconductor memory device. The other gate electrodes 120 of the plurality of gate electrodes 120 may be provided as a string select line SSL of the semiconductor memory device. For example, among the plurality of gate electrodes 120, the gate electrodes 120 adjacent to the common source plate 105 may be provided as the ground select line GSL. Among the plurality of gate electrodes 120, the gate electrode 120 adjacent to the first bonding pad 195 may be provided as the string select line SSL. However, example embodiments are not limited thereto. The arrangement and number of the ground select lines GSL and the string select lines SSL may vary.

In some example embodiments, some of the plurality of gate electrodes 120 may be used as an erase control line (ECL) of the semiconductor memory device. The erase control line ECL may be used as a gate electrode of an erase transistor. The erase transistor may generate a gate induced drain leakage (GIDL) to perform an erase operation on a plurality of memory cell transistors.

Although not illustrated, in some example embodiments, the plurality of gate electrodes 120 may extend in the first direction D1 and be disposed on the connection area CA. Each of the plurality of gate electrodes 120 may extend to different lengths to form a stepped structure having a staircase shape. By the stepped structure, a specific gate electrode 120 may include an end portion exposed by the gate electrode 120 disposed above the specific gate electrode 120. A word line contact may be formed on the end portion of the gate electrode 120.

Each of the gate electrodes 120 may include a conductive material, for example, a metal such as tungsten (W), cobalt (Co), and nickel (Ni), or a semiconductor material such as silicon, but example embodiments are not limited thereto.

The mold insulating layer 110 may include an insulating material. For example, the mold insulating layer 110 may include at least one of silicon oxide, silicon nitride, and silicon oxynitride, but example embodiments are not limited thereto.

The channel structure CH may be disposed on the cell array area MCA. The channel structure CH may be formed through the mold structure MS. For example, the channel structure CH may be formed through each of the plurality of mold insulating layers 110 and the plurality of gate electrodes 120. The channel structure CH1 may intersect the plurality of gate electrodes 120. The channel structure CH may be disposed in a channel hole extending in the third direction D3. The channel structure CH may have a pillar shape (e.g., a cylindrical shape) extending in the third direction D3.

In some example embodiments, due to a high aspect ratio of the mold structure MS, a cross-section of the channel structure CH may have an inclined side surface with a width that decreases towards the cell substrate 100. However, example embodiments are not limited thereto.

The channel structure CH may include an information storage film 140, the semiconductor pattern 148, and a filling pattern 149.

The semiconductor pattern 148 may extend in the third direction D3 and be formed through the mold structure MS. One end of the semiconductor pattern 148 may be formed through an upper surface of the common source plate 105. One end of the semiconductor pattern 148 may be disposed in the common source plate 105. Although it is illustrated that the semiconductor pattern 148 has a cup shape, example embodiments are not limited thereto. For example, the semiconductor pattern 148 may have various shapes such as a cylindrical shape, a rectangular cylindrical shape, a solid pillar shape, etc. For example, the semiconductor pattern 148 may include a semiconductor material such as a single crystal silicon, a polycrystalline silicon, an organic semiconductor material, a carbon nanostructure, etc., but example embodiments are not limited thereto.

The information storage film 140 may be interposed between the semiconductor pattern 148 and each of the first gate electrodes 120 and the semiconductor pattern 148. For example, the information storage film 140 may extend along an outer surface of the semiconductor pattern 148. For example, the information storage film 140 may include at least one of silicon oxide, silicon nitride, silicon oxynitride, and a high-k material having a higher dielectric constant than the silicon oxide. For example, the high-k material may include at least one of aluminum oxide, hafnium oxide, lanthanum oxide, tantalum oxide, titanium oxide, lanthanum hafnium oxide, lanthanum aluminum oxide, dysprosium scandium oxide, and a combination thereof. However, example embodiments are not limited thereto.

In some example embodiments, when viewed in a plan view, the channel structures CH may be arranged in a zigzag shape. For example, the channel structures CH may be arranged in a staggered manner in the first direction D1 and a second direction D2. The channel structures CH disposed in the zigzag form may further improve the integration density of the semiconductor memory device. In some example embodiments, the channel structures CH may be arranged in a honeycomb form.

In some example embodiments, the information storage film 140 may include multiple films. The information storage film 140 may include a tunnel insulating film 142, a charge storage film 144, and a blocking insulating film 146, which may be stacked in order on the outer surface of the semiconductor pattern 148.

For example, the tunnel insulating film 142 may include the silicon oxide or a high-k material (e.g., aluminum oxide (Al₂O₃), hafnium oxide (HfO₂)) having a higher dielectric constant than the silicon oxide. For example, the charge storage film 144 may include silicon nitride. For example, the blocking insulating film 146 may include the silicon oxide or a high-k material (e.g., aluminum oxide (Al₂O₃) or hafnium oxide (HfO₂)) having a higher dielectric constant than the silicon oxide. However, example embodiments are not limited thereto.

In some example embodiments, the channel structure CH may further include the filling pattern 149. The filling pattern 149 may be formed to fill the interior of the semiconductor pattern 148 in the cup shape. For example, the filling pattern 149 may include an insulating material such as silicon oxide, but example embodiments are not limited thereto.

The channel pad 182 may be disposed on the channel structure CH. The channel pad 182 may be disposed on the channel structure CH and electrically connected to the semiconductor pattern 148. The channel contact 185 may be disposed on the channel pad 182.

For example, the channel pad 182 may include polysilicon doped with an impurity, but example embodiments are not limited thereto. The channel contact 185 may include, for example, a conductive material such as tungsten (W), copper (Cu), aluminum (Al), molybdenum (Mo).

The cell interlayer insulating film 180 may cover the mold structure MS and the channel structure CH. The channel contact 185 may be disposed in the cell interlayer insulating film 180. The first bonding pad 195 may be disposed on the cell interlayer insulating film 180. The cell interlayer insulating film 180 may surround a lower surface and a side surface of the first bonding pad 195. The cell interlayer insulating film 180 may not be disposed on an upper surface of the first bonding pad 195.

The insulating substrate 101 may be disposed on the cell substrate 100 in the connection area CA. However, example embodiments are not limited thereto. In some example embodiments, the cell substrate 100 may be omitted from the connection area CA, and the insulating substrate 101 may be disposed thereon. For example, the insulating substrate 101 may include at least one of silicon oxide, silicon nitride, silicon oxynitride, and silicon carbide, but example embodiments are not limited thereto.

The first connection via 150 may be disposed on the common source plate 105 in the connection area CA. The first connection via 150 may extend in the cell interlayer insulating film 180 in the third direction D3. The first connection via 150 may be electrically connected to the common source plate 105. A connection contact 165 may be disposed on the first connection via 150.

The second connection via 160 may be formed through the insulating substrate 101 in the connection area CA and disposed on the cell substrate 100. The second connection via 160 may extend in the cell interlayer insulating film 180 in the third direction D3. In some example embodiments, the second connection via 160 may be connected to the cell substrate 100. The connection contact 165 may be disposed on the second connection via 160.

The first connection via 150 and the second connection via 160 may have a cylindrical or conical shape. According to a high aspect ratio, a width of each of the first connection via 150 and the second connection via 160 may increase as a distance from the cell substrate 100 increases.

In some example embodiments, each of the first connection via 150 and the second connection via 160 may include a conductive layer and a barrier layer. The barrier layer may surround the conductive layer. The barrier layer may include at least one of, for example, titanium (Ti), titanium nitride (TiN), tantalum (Ta), tantalum nitride (TaN), tungsten nitride (WN), and tungsten carbon nitride (WCN). For example, the conductive layer may include a metal material such as tungsten (W), copper (Cu), aluminum (Al), molybdenum (Mo). However, example embodiments are not limited thereto.

The first bonding pad 195 may be disposed on an upper surface of the cell interlayer insulating film 180. The first bonding pad 195 may be connected to the connection contact 165 and the channel contact 185. Although it is illustrated that the first bonding pad 195 is in direct contact with each of the connection contact 165 and the channel contact 185, example embodiments are not limited thereto. A wiring structure may be formed between the first bonding pad 195 and the connection contact 165 and between the first bonding pad 195 and the channel contact 185 to be connected to each other.

The first bonding insulating layer 192 may be disposed on the upper surface of the cell interlayer insulating film 180. The first bonding insulating layer 192 may surround the first bonding pad 195 in the first and second directions D1 and D2. The thickness of the first bonding insulating layer 192 in the third direction D3 may be smaller than the thickness of the first bonding pad 195 in the third direction D3, but example embodiments are not limited thereto.

A second bonding pad 295 may be disposed on the first bonding pad 195. A wiring insulating film 280 may surround upper and side surfaces of the second bonding pad 295. The wiring insulating film 280 may not be disposed on a lower surface of the second bonding pad 295. The lower surface of the second bonding pad 295 may be in contact with the upper surface of the first bonding pad 195.

A second bonding insulating layer 292 may be disposed on a lower surface of the wiring insulating film 280. The second bonding insulating layer 292 may surround the second bonding pad 295 in the first and second directions D1 and D2. The thickness of the second bonding insulating layer 292 in the third direction D3 may be smaller than the thickness of the second bonding pad 295 in the third direction D3, but example embodiments are not limited thereto.

Each of the first bonding insulating layer 192 and the second bonding insulating layer 292 may include at least one of, for example, silicon carbonitride (SiCN), silicon oxide (SiO), silicon nitride (SiN), silicon oxide carbonate (SiOC), silicon oxynitride (SiON), and silicon oxycarbonitride (SiOCN). However, example embodiments are not limited thereto.

The first bonding pad 195 may be connected to the second bonding pad 295. The first bonding insulating layer 192 may be connected to the second bonding insulating layer 292. The first bonding pad 195 and the second bonding pad 295 may be bonded or connected in direct contact with each other by hybrid bonding, and the first bonding insulating layer 192 and the second bonding insulating layer 292 may be bonded or connected in direct contact with each other by hybrid bonding. For example, the first bonding pad 195 and the second bonding pad 295 may be coupled in contact with each other by copper-to-copper bonding, and the first bonding insulating layer 192 and the second bonding insulating layer 292 may be coupled in contact with each other by dielectric-to-dielectric bonding. The first bonding pad 195 and the second bonding pad 295 may be provided between the cell structure CELL and the peripheral circuit structure PERI as an electrical connection path.

The peripheral circuit structure PERI may include a first peripheral circuit substrate 200, a second peripheral circuit substrate 300, a liner layer 210, a pad contact 220, a first pad 230, a through via 240, a second pad 250, a peripheral circuit insulating film 260, a first peripheral circuit transistor 265, a second peripheral circuit transistor 365, a first upper insulating film 272, a second upper insulating film 274, the wiring insulating film 280, a peripheral circuit wiring structure 290, the second bonding pad 295, etc.

The peripheral circuit wiring structure 290 may be disposed in the peripheral circuit insulating film 260. The peripheral circuit wiring structure 290 may be connected to the second bonding pad 295. The peripheral circuit wiring structure 290 may be electrically connected to the first peripheral circuit transistor 265 and the second peripheral circuit transistor 365. The peripheral circuit wiring structure 290 may be provided as an electrical connection path between the second bonding pad 295 and the first peripheral circuit transistor 265 and between the second bonding pad 295 and the second peripheral circuit transistor 365.

The peripheral circuit wiring structure 290 may include a plurality of wiring layers. In some example embodiments, the thickness of the wiring layer of the peripheral circuit wiring structure 290 may not be the same. For example, the thickness of the wiring layer adjacent to the second bonding pad 295 may be greater than the thickness of the wiring layer adjacent to the first peripheral circuit transistor 265. The thickness may refer to a thickness in the third direction D3. However, example embodiments are not limited thereto. For example, the thickness of the wiring layer of the peripheral circuit wiring structure 290 may be the same.

The peripheral circuit insulating film 260 may be disposed on the wiring insulating film 280. The peripheral circuit insulating film 260 may surround the first peripheral circuit transistor 265 and the second peripheral circuit transistor 365. The peripheral circuit insulating film 260 may be disposed above and below the first peripheral circuit substrate 200 and above and below the second peripheral circuit substrate 300.

The other components of the peripheral circuit structure PERI will be described in detail below with reference to FIGS. 2 and 4.

The first peripheral circuit substrate 200 may include a semiconductor substrate such as a silicon substrate, a germanium substrate, or a silicon-germanium substrate. Alternatively, the first peripheral circuit substrate 200 may include a silicon-on-insulator (SOI) substrate or a germanium-on-insulator (GOI) substrate, etc. However, example embodiments are not limited thereto. In some example embodiments, the first peripheral circuit substrate 200 may include polysilicon (poly Si).

The first peripheral circuit substrate 200 may include a third surface 200_A and a fourth surface 200_B opposite to the third surface 200_A. The third surface 200_A of the first peripheral circuit substrate 200 may be opposite to the second surface 100_B of the cell substrate 100. The third surface 200_A of the first peripheral circuit substrate 200 may be referred to as a front side of the first peripheral circuit substrate 200, and the fourth surface 200_B of the first peripheral circuit substrate 200 may be referred to as a back side of the first peripheral circuit substrate 200.

The first peripheral circuit transistor 265 may be disposed on the third surface 200_A of the first peripheral circuit substrate 200. A first device isolation trench ST1 may be formed in the first peripheral circuit substrate 200. The first device isolation trench ST1 may be disposed on at least one side of the first peripheral circuit transistor 265. For example, the first device isolation trench ST1 may be disposed between the first peripheral circuit transistors 265 adjacent to each other in the first direction D1.

The first peripheral circuit substrate 200 may include a protrusion 205 protruding from the fourth surface 200_B of the first peripheral circuit substrate 200 in the third direction D3. The protrusion 205 may protrude from the fourth surface 200_B of the first peripheral circuit substrate 200 toward the first pad 230. The width of the protrusion 205 in the first direction D1 may decrease as a distance from the fourth surface 200_B of the first peripheral circuit substrate 200 increases.

In some example embodiments, the first device isolation trench ST1 may overlap the protrusion 205 in the third direction D3. However, example embodiments are not limited thereto. For example, the first device isolation trench ST1 may overlap at least a portion of the protrusion 205 in the third direction D3, or the first device isolation trench ST1 may not overlap the protrusion 205.

The liner layer 210 may be disposed on the first peripheral circuit substrate 200. The liner layer 210 may be in contact with the first peripheral circuit substrate 200. The liner layer 210 may extend along the fourth surface 200_B of the first peripheral circuit substrate 200 and upper and side surfaces of the protrusion 205. In some example embodiments, the liner layer 210 may cover the fourth surface 200_B of the first peripheral circuit substrate 200 and the upper and side surfaces of the protrusion 205.

In some example embodiments, the liner layer 210 may be conformally formed. For example, the liner layer 210 may have the same thickness in the third direction D3. However, example embodiments are not limited thereto.

The liner layer 210 may include a material with higher thermal conductivity than the first peripheral circuit substrate 200. The liner layer 210 may include, for example, a metal material.

Electrical characteristics of the semiconductor memory device may deteriorate due to heat generated by the transistor. The semiconductor memory device according to some example embodiments includes the liner layer 210 formed on the first peripheral circuit substrate 200. The heat generated by the first peripheral circuit transistor 265 may be conducted to the first pad 230 along the liner layer 210 with a relatively high thermal conductivity and may be dissipated outside of the device. As a result, reliability and/or electrical characteristics of the semiconductor memory device may be improved.

The pad contact 220 may be disposed on the first peripheral circuit substrate 200. The pad contact 220 may be disposed on an upper surface of the protrusion 205 of the first peripheral circuit substrate 200. In some example embodiments, the pad contact 220 may be formed through the liner layer 210 and may be in contact with the upper surface of the protrusion 205. Unlike the illustration, an end portion of the pad contact 220 may be formed through the upper surface of the protrusion 205 and disposed inside the protrusion 205. The pad contact 220 may be in contact with the liner layer 210. For example, the end portion of the pad contact 220 may be surrounded by the liner layer 210.

Although it is illustrated that the pad contact 220 is disposed only on the protrusion 205, example embodiments are not limited thereto. For example, the pad contact 220 may be disposed on the fourth surface 200_B of the first peripheral circuit substrate 200 between the protrusion 205 and the adjacent protrusion 205.

The first pad 230 may be disposed on the pad contact 220 and the peripheral circuit insulating film 260. A lower surface of the first pad 230 may be connected to the pad contact 220. For example, the lower surface of the first pad 230 may be in contact with the pad contact 220. The first pad 230 may include, for example, a metal material. The metal material may be any one of aluminum (Al), copper (Cu), cobalt (Co), tungsten (W), but example embodiments are not limited thereto.

The first upper insulating film 272 may be disposed on the peripheral circuit insulating film 260. The second upper insulating film 274 may be disposed on the first upper insulating film 272. In some example embodiments, the first upper insulating film 272 may include a material different from that of the second upper insulating film 274. For example, the first upper insulating film 272 may include silicon nitride, and the second upper insulating film 274 may include silicon oxide. However, example embodiments are not limited thereto.

A first trench T1 may be disposed in the peripheral circuit insulating film 260. The peripheral circuit insulating film 260, the first upper insulating film 272, and the second upper insulating film 274 may define a side surface of the first trench T1. The peripheral circuit insulating film 260 may define a bottom surface of the first trench T1. The bottom surface of the first trench T1 may be disposed at a lower level than an upper surface 230_US of the first pad 230.

The first trench T1 may expose a portion of the first pad 230. For example, the first trench T1 may expose the upper surface 230_US and at least a portion of a side surface 230_SS of the first pad 230. In some example embodiments, the width of the bottom surface of the first trench T1 in the first direction D1 may be greater than the width of the first pad 230 in the first direction D1.

By increasing the width of the bottom surface of the first trench T1 in the first direction D1, when exposed, the area of the first pad 230 may be increased. As the upper surface 230_US and portion of the side surface 230_SS of the first pad 230 are exposed by the first trench T1, the heat dissipated from the first pad 230 outside of the device may be increased.

The through via 240 may extend in the third direction D3 and be formed through the peripheral circuit insulating film 260. The through via 240 may be disposed to be spaced apart from the first peripheral circuit substrate 200. The peripheral circuit insulating film 260 may be disposed between the through via 240 and the first peripheral circuit substrate 200. One end of the through via 240 may be connected to the peripheral circuit wiring structure 290. The second pad 250 may be disposed on the other end of the through via 240.

In some example embodiments, the width of the through via 240 may increase as a distance from the peripheral circuit wiring structure 290 increases. In other words, the width of the through via 240 may decrease as a distance from the second pad 250 increases. From the perspective of cross-sectional area, the through via 240 may have a tapered shape.

The second pad 250 may be disposed on the through via 240. In some example embodiments, the second pad 250 may be disposed at the same level as the first pad 230. In other words, the upper surface 230_US of the first pad 230 may be disposed on the same plane as an upper surface 250_US of the second pad 250.

A second trench T2 may be disposed in the peripheral circuit insulating film 260. The peripheral circuit insulating film 260, the first upper insulating film 272, and the second upper insulating film 274 may define a side surface of the second trench T2. The peripheral circuit insulating film 260 may define a bottom surface of the second trench T2. The bottom surface of the second trench T2 may be disposed at a lower level than the upper surface 250_US of the second pad 250.

The second trench T2 may expose a portion of the second pad 250. For example, the second trench T2 may expose the upper surface 250_US and at least a portion of a side surface 250_SS of the second pad 250. In some example embodiments, the width of the bottom surface of the second trench T2 in the first direction D1 may be greater than the width of the second pad 250 in the first direction D1.

Referring back to FIG. 2, the second peripheral circuit substrate 300 may be disposed on the peripheral circuit wiring structure 290. The second peripheral circuit substrate 300 may include a semiconductor substrate such as a silicon substrate, a germanium substrate, or a silicon-germanium substrate. Alternatively, the first peripheral circuit substrate 200 may include a silicon-on-insulator (SOI) substrate or a germanium-on-insulator (GOI) substrate, etc. However, example embodiments are not limited thereto. In some example embodiments, the second peripheral circuit substrate 300 may include polysilicon (poly Si).

The first peripheral circuit substrate 200 may be disposed to be spaced apart from the second peripheral circuit substrate 300. In another aspect, the first peripheral circuit substrate 200 and the second peripheral circuit substrate 300 may not be spaced apart and may be connected to each other.

The second peripheral circuit substrate 300 may include a fifth surface and a sixth surface opposite to the fifth surface. The fifth surface of the second peripheral circuit substrate 300 may be opposite to the second surface 100_B of the cell substrate 100. The fifth surface of the second peripheral circuit substrate 300 may be referred to as a front side of the second peripheral circuit substrate 300, and the sixth surface of the second peripheral circuit substrate 300 may be referred to as a back side of the second peripheral circuit substrate 300.

The second peripheral circuit transistor 365 may be disposed on the fifth surface of the second peripheral circuit substrate 300. A second device isolation trench ST2 may be formed in the second peripheral circuit substrate 300. The second device isolation trench ST2 may be disposed on at least one side of the second peripheral circuit transistor 365. For example, the second device isolation trench ST2 may be disposed between the second peripheral circuit transistors 365 adjacent to each other in the first direction D1.

Each of the first peripheral circuit transistor 265 and the second peripheral circuit transistor 365 may include a circuit gate dielectric layer, a circuit gate electrode, a spacer, and a source/drain region. The source/drain regions including impurities may be disposed on both sides of the circuit gate electrode. The spacers may be disposed on both sides of the circuit gate electrode.

The circuit gate dielectric layer may include silicon oxide, silicon nitride, or a high-k material. The circuit gate electrode may include at least one of titanium nitride (TiN), tantalum nitride (TaN), tungsten nitride (WN), titanium silicon nitride (TiSiN), tantalum silicon nitride (TaSiN), tungsten silicon nitride (WSiN), tungsten (W), copper (Cu), aluminum (Al), molybdenum (Mo), and ruthenium (Ru). The circuit gate electrode may include a semiconductor layer, for example, a doped polycrystalline silicon layer. However, example embodiments are not limited thereto.

The peripheral circuit wiring structure 290 may be electrically connected to the circuit gate electrode and the source/drain region of each of the first peripheral circuit transistor 265 and the second peripheral circuit transistor 365. For example, the peripheral circuit wiring structure 290 and the source/drain region may be electrically connected to each other through a source/drain contact.

Although it is illustrated that the transistor is disposed on the first peripheral circuit substrate 200 and the second peripheral circuit substrate 300, example embodiments are not limited thereto. For example, not only various active elements such as transistors, etc., but also various passive elements such as capacitors, registers, inductors, etc. may be included on the first peripheral circuit substrate 200 and the second peripheral circuit substrate 300.

The first peripheral circuit transistor 265 may configure a peripheral circuit for controlling data input/output operations of the semiconductor memory device. For example, the first peripheral circuit transistor 265 may configure the data input/output circuit of FIG. 1. The second peripheral circuit transistor 365 may configure a peripheral circuit controlling an operation of the semiconductor memory device. For example, the second peripheral circuit transistor 365 may configure the row decoder DEC, the page buffer PB, the other peripheral circuits PC, etc. of FIG. 1. However, example embodiments are not limited thereto. For example, the first peripheral circuit transistor 265 may configure the row decoder DEC, the page buffer PB, other peripheral circuits PC, etc. of FIG. 1.

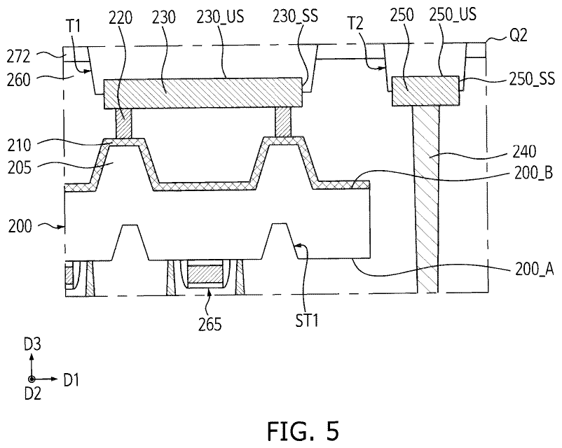

FIG. 5 is a diagram provided to explain a semiconductor memory device according to some example embodiments. FIG. 5 may correspond to an enlarged view provided to explain the region Q2 of FIG. 2. For convenience of explanation, different configurations from those described with reference to FIGS. 2 to 4 will be mainly described.

Referring to FIG. 5, in the semiconductor memory device according to some example embodiments, the liner layer 210 may be disposed on the first peripheral circuit substrate 200. The liner layer 210 may extend along the fourth surface 200_B of the first peripheral circuit substrate 200 and the upper and side surfaces of the protrusion 205. The liner layer 210 may completely cover the upper and side surfaces of the protrusion 205.

The liner layer 210 may be disposed between the protrusion 205 and the pad contact 220. The pad contact 220 may be spaced apart from the protrusion 205 in the third direction D3. One end of the pad contact 220 may be in contact with the liner layer 210.

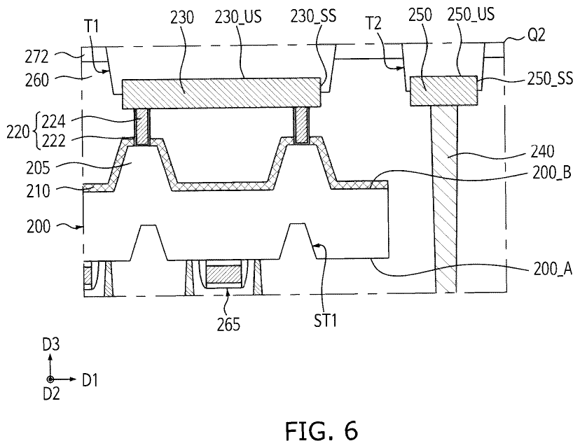

FIG. 6 is a diagram provided to explain a semiconductor memory device according to some example embodiments. FIG. 6 may correspond to an enlarged view provided to explain the region Q2 of FIG. 2. For convenience of explanation, different configurations from those described with reference to FIGS. 2 to 4 will be mainly described.

Referring to FIG. 6, in the semiconductor memory device according to some example embodiments, the pad contact 220 may include a contact barrier layer 222 and a contact filling layer 224.

The contact barrier layer 222 may define an outer shape of the pad contact 220. The contact barrier layer 222 may be in contact with the liner layer 210 and the protrusion 205. The contact filling layer 224 may be disposed in the contact barrier layer 222. The contact filling layer 224 may fill the interior of the contact barrier layer 222.

The contact barrier layer 222 may include at least one of, for example, titanium (Ti), titanium nitride (TiN), tantalum (Ta), tantalum nitride (TaN), tungsten nitride (WN), and tungsten carbon nitride (WCN). The contact filling layer 224 may include, for example, a metal material such as tungsten (W), copper (Cu), aluminum (Al), or molybdenum (Mo). However, example embodiments are not limited thereto.

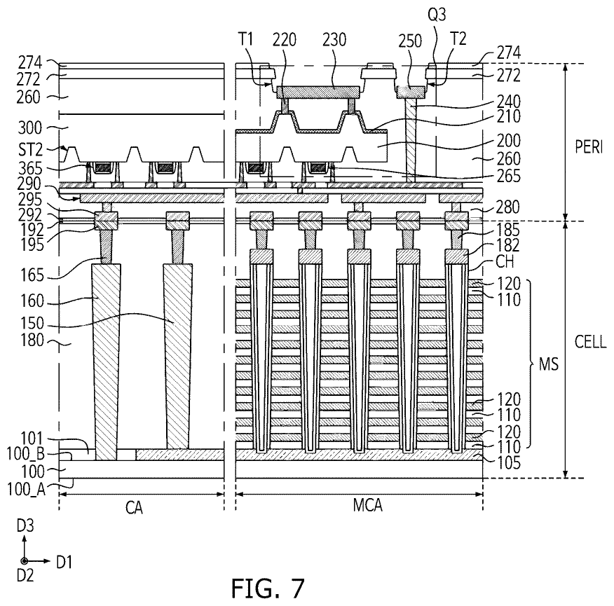

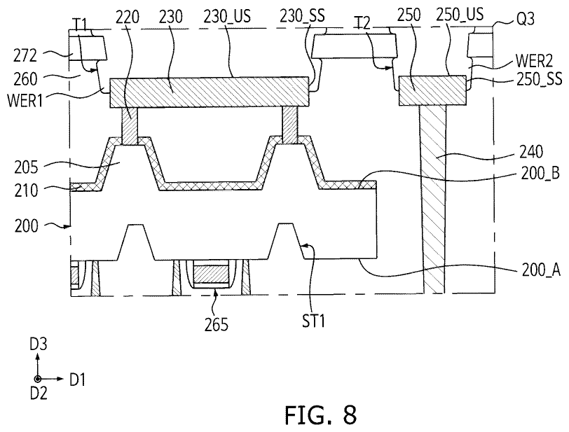

FIGS. 7 and 8 are diagrams provided to explain a semiconductor memory device according to some example embodiments. For reference, FIG. 7 is a cross-sectional view taken along the first direction D1 of a portion of the cell array area MCA and a portion of the connection area CA of the semiconductor memory device of FIG. 1, and FIG. 8 is an enlarged view provided to explain the region Q3 of FIG. 7. For convenience of explanation, different configurations from those described with reference to FIGS. 2 to 4 will be mainly described.

Referring to FIGS. 7 and 8, in the semiconductor memory device according to some example embodiments, the first trench T1 may include a first width expansion region WER1. The first trench T1 may be defined by the peripheral circuit insulating film 260, the first upper insulating film 272, and the second upper insulating film 274. The first width expansion region WER1 may be disposed in the peripheral circuit insulating film 260. The width of the first trench T1 in the first direction D1 may increase due to the first width expansion region WER1. The first width expansion region WER1 may expose at least a portion of the side surface 230_SS of the first pad 230.

The second trench T2 may include a second width expansion region WER2. The second trench T2 may be defined by the peripheral circuit insulating film 260, the first upper insulating film 272, and the second upper insulating film 274. The second width expansion region WER2 may be disposed in the peripheral circuit insulating film 260. The width of the second trench T2 in the first direction D1 may increase due to the second width expansion region WER2. The second width expansion region WER2 may expose at least a portion of the side surface 250_SS of the second pad 250.

A step may be formed between the peripheral circuit insulating film 260 and the first upper insulating film 272 disposed on the side surface of the first trench T1, and between the first upper insulating film 272 and the second upper insulating film 274. The first upper insulating film 272 disposed on the side surface of the first trench T1 may protrude beyond each of the peripheral circuit insulating film 260 and the second upper insulating film 274 in the first direction D1.

A step may be formed between the peripheral circuit insulating film 260 and the first upper insulating film 272 disposed on the side surface of the second trench T2, and between the first upper insulating film 272 and the second upper insulating film 274. The first upper insulating film 272 disposed on the side surface of the second trench T2 may protrude beyond each of the peripheral circuit insulating film 260 and the second upper insulating film 274 in the first direction D1.

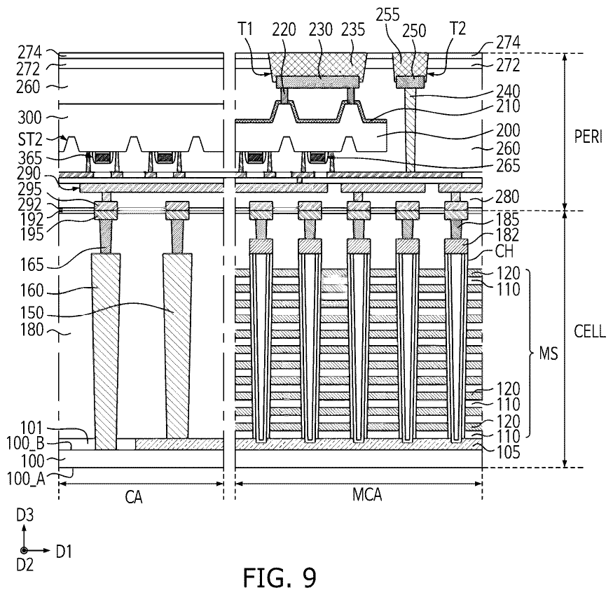

FIG. 9 is a diagram provided to explain a semiconductor memory device according to some example embodiments. For reference, FIG. 9 is a cross-sectional view taken along the first direction D1 of a portion of the cell array area MCA and a portion of the connection area CA of the semiconductor memory device of FIG. 1. For convenience of explanation, different configurations from those described with reference to FIGS. 2 to 4 will be mainly described.

Referring to FIG. 9, the peripheral circuit structure PERI of the semiconductor memory device according to some example embodiments may further include a first filling layer 235 and a second filling layer 255.

The first filling layer 235 may be disposed on the first trench T1. The first filling layer 235 may fill the first trench T1. The first filling layer 235 may be in contact with the first pad 230. For example, the first filling layer 235 may be in contact with the upper surface and at least a portion of the side surface of the first pad 230. The first filling layer 235 may include a material with high thermal conductivity. The first filling layer 235 may include, for example, a metal material.

The second filling layer 255 may be disposed on the second trench T2. The second filling layer 255 may fill the second trench T2. The second filling layer 255 may be in contact with the second pad 250. For example, the second filling layer 255 may be in contact with the upper surface and at least a portion of the side surface of the second pad 250. The second filling layer 255 may include a conductive material. In some example embodiments, the first filling layer 235 and the second filling layer 255 may include the same material. However, example embodiments are not limited thereto.

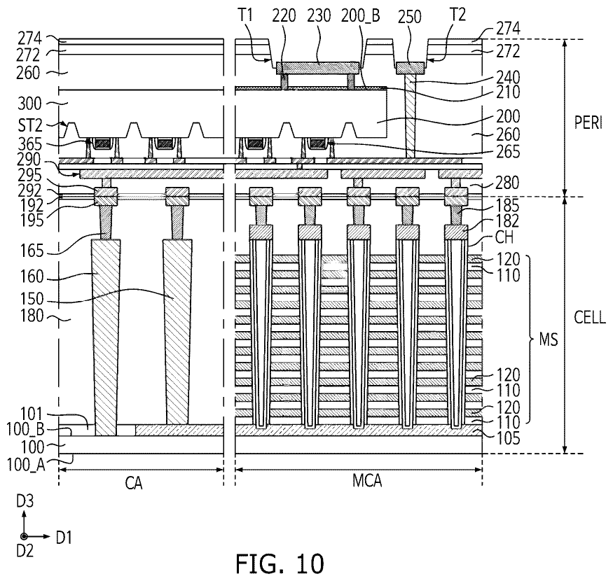

FIG. 10 is a diagram provided to explain a semiconductor memory device according to some example embodiments. For reference, FIG. 10 is a cross-sectional view taken along the first direction D1 of a portion of the cell array area MCA and a portion of the connection area CA of the semiconductor memory device of FIG. 1. For convenience of explanation, different configurations from those described with reference to FIGS. 2 to 4 will be mainly described.

Referring to FIG. 10, in the semiconductor memory device according to some example embodiments, the liner layer 210 may be disposed on the fourth surface 200_B of the first peripheral circuit substrate 200.

The liner layer 210 may extend along the fourth surface 200_B of the first peripheral circuit substrate 200 in the first and second directions D1 and D2. Although it is illustrated that the liner layer 210 is not disposed on the second peripheral circuit substrate 300, example embodiments are not limited thereto. For example, the liner layer 210 may be disposed on the back side of the second peripheral circuit substrate 300. The liner layer 210 on the second peripheral circuit substrate 300 and the liner layer 210 on the first peripheral circuit substrate 200 may be disposed at the same level.

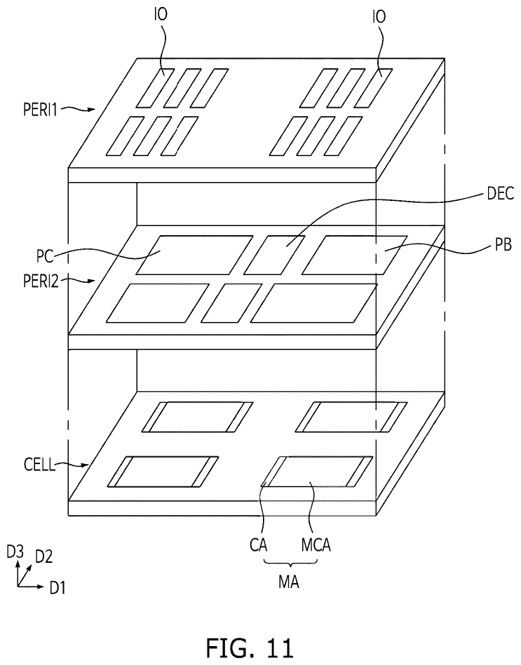

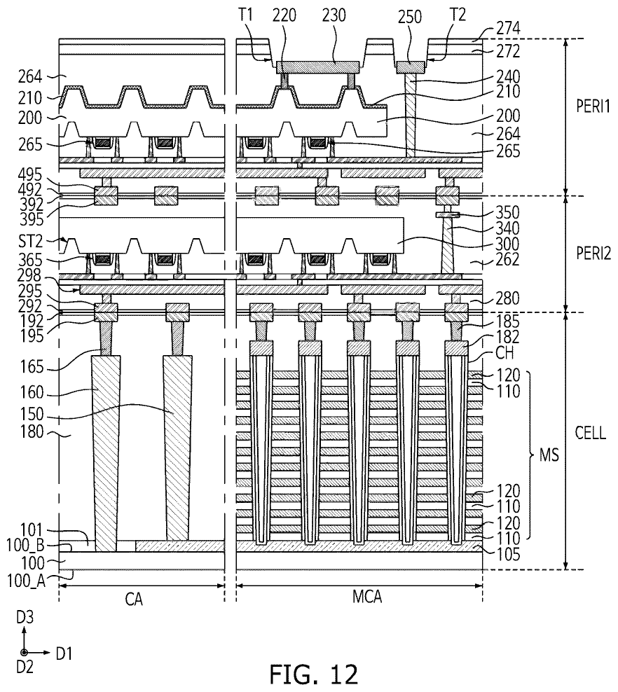

FIG. 11 is a schematic exploded perspective view provided to explain a semiconductor memory device according to some example embodiments. FIG. 12 is a diagram provided to explain a semiconductor memory device according to some example embodiments. For reference, FIG. 12 is a cross-sectional view taken along the first direction D1 of a portion of the memory cell array area MCA and a portion of the connection area CA of FIG. 11. For convenience of explanation, different configurations from those described with reference to FIGS. 1 to 4 will be mainly described.

Referring to FIG. 11, the semiconductor memory device according to some example embodiments may include the cell structure CELL, a first peripheral circuit structure PERI1, and a second peripheral circuit structure PERI2. The second peripheral circuit structure PERI2 may be stacked on the cell structure CELL. The first peripheral circuit structure PERI1 may be stacked on the second peripheral circuit structure PERI2. The second peripheral circuit structure PERI2 may include the row decoder DEC, the page buffer PB, and the other peripheral circuits PC. The first peripheral circuit structure PERI1 may include the data input/output circuit IO and a heat dissipation pad part connected to the data input/output circuit IO.

Referring to FIG. 12, the cell structure CELL and the second peripheral circuit structure PERI2 may be coupled to each other. For example, the first bonding pad 195 of the cell structure CELL and the second bonding pad 295 of the second peripheral circuit structure PERI2 may be bonded to each other.

The second peripheral circuit structure PERI2 may include the second peripheral circuit substrate 300, a third connection via 340, a via pad 350, the second peripheral circuit transistor 365, a first peripheral circuit insulating film 262, a third bonding pad 395, a third bonding insulating layer 392, etc.

The description of the second peripheral circuit substrate 300 and the second peripheral circuit transistor 365 may be similar to that described above. The second peripheral circuit transistor 365 may be electrically connected to a first peripheral circuit wiring structure 298. The third connection via 340 may be formed through the first peripheral circuit insulating film 262 and connected to the first peripheral circuit wiring structure 298. The via pad 350 may be disposed on the third connection via 340. The third connection via 340 may be connected to the third bonding pad 395 through the via pad 350.

The third bonding pad 395 and the third bonding insulating layer 392 may be disposed on the first peripheral circuit insulating film 262. A fourth bonding pad 495 may be disposed on the third bonding pad 395. A fourth bonding insulating layer 492 may be disposed on the third bonding insulating layer 392. The third bonding pad 395 and the fourth bonding pad 495 may be bonded or connected in direct contact with each other by hybrid bonding, and the third bonding insulating layer 392 and the fourth bonding insulating layer 492 may be bonded or connected in direct contact with each other by hybrid bonding. For example, the third bonding pad 395 and the fourth bonding pad 495 may be coupled in contact with each other by copper-to-copper bonding, and the third bonding insulating layer 392 and the fourth bonding insulating layer 492 may be coupled in contact with each other by dielectric-to-dielectric bonding. The third bonding pad 395 and the fourth bonding pad 495 may be provided as an electrical connection path between the first peripheral circuit structure PERI1 and the second peripheral circuit structure PERI2.

The first peripheral circuit structure PERI1 may be stacked on the second peripheral circuit structure PERI2. The first peripheral circuit structure PERI1 may be bonded to the second peripheral circuit structure PERI2.

The first peripheral circuit structure PERI1 may include the first peripheral circuit substrate 200, the liner layer 210, the pad contact 220, the first pad 230, the through via 240, the second pad 250, a second peripheral circuit insulating film 264, the first peripheral circuit transistor 265, etc. The first peripheral circuit transistor 265 may configure an input/output data circuit.

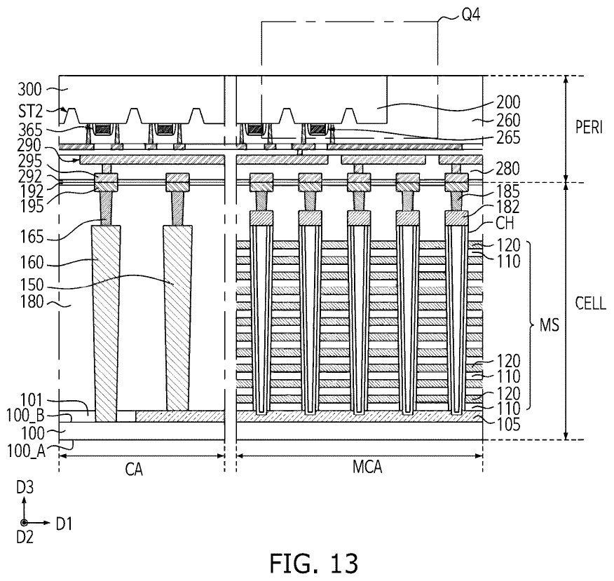

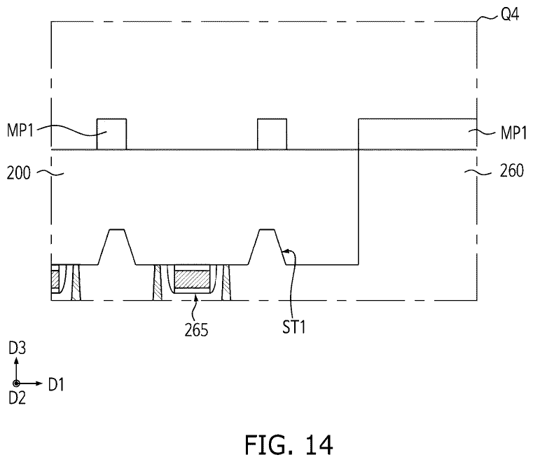

FIGS. 13 to 25 are diagrams showing intermediate stages, provided to explain a method for manufacturing a semiconductor memory device according to some example embodiments. For reference, FIG. 13 is a cross-sectional view taken along the first direction D1 of a portion of the memory cell array area MCA and a portion of the connection area CA of the semiconductor memory device, and FIGS. 14 to 25 are enlarged views of the region Q4 of FIG. 13.

Referring to FIG. 13, the method for manufacturing the semiconductor memory device according to some example embodiments may include stacking the peripheral circuit structure PERI on the cell structure CELL.

Specifically, the cell structure CELL may be formed on a first wafer, the peripheral circuit structure PERI may be formed on a second wafer, and the first wafer and the second wafer may be bonded to each other. For example, the first bonding pad 195 of the cell structure CELL and the second bonding pad 295 of the peripheral circuit structure PERI may be bonded to each other. The description of the capacitor structure CELL may be the same as that described above with reference to FIGS. 2 to 4. The peripheral circuit structure PERI may include the first peripheral circuit substrate 200, the second peripheral circuit substrate 300, the first peripheral circuit transistor 265, the second peripheral circuit transistor 365, the peripheral circuit insulating film 260, the peripheral circuit wiring structure 290, the second bonding pad 295, etc.

Referring to FIG. 14, a first mask pattern MP1 may be formed on the first peripheral circuit substrate 200 and the peripheral circuit insulating film 260. The first mask pattern MP1 may cover an upper surface of the peripheral circuit insulating film 260. The first mask pattern MP1 may expose a portion of the upper surface of the first peripheral circuit substrate 200. In some example embodiments, the first mask pattern MP1 may overlap the first device isolation trench ST1 in the third direction D3.

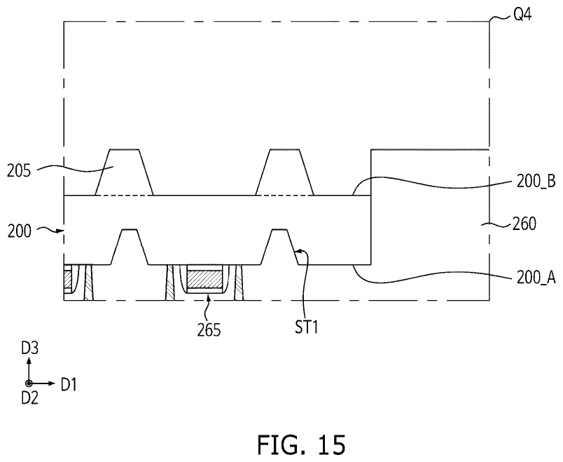

Referring to FIGS. 14 and 15, an etching process may be performed on the first peripheral circuit substrate 200 using the first mask pattern MP1 as an etching mask. A portion of the first peripheral circuit substrate 200 may be removed by the etching process to form the protrusion 205. The first mask pattern MP1 may be removed.

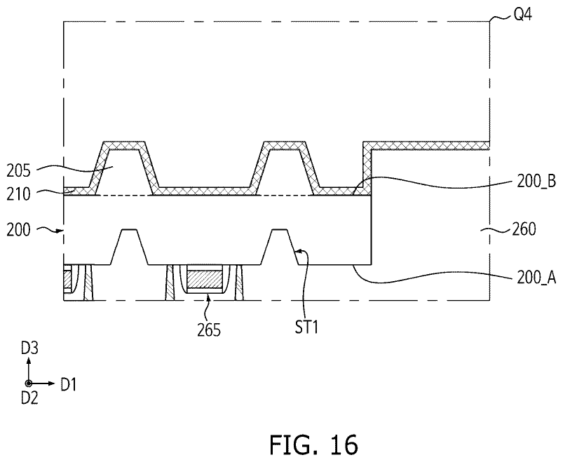

Referring to FIG. 16, the liner layer 210 may be formed on the first peripheral circuit substrate 200 and the peripheral circuit insulating film 260. For example, the liner layer 210 may be formed on the fourth surface 200_B of the first peripheral circuit substrate 200, the upper and side surfaces of the protrusion 205, and the peripheral circuit insulating film 260.

The liner layer 210 may include a metal material. For example, the liner layer 210 may be formed using a chemical vapor deposition (CVD) method, a physical vapor deposition (PVD) method, or an atomic layer deposition (ALD) method. In some example embodiments, the liner layer 210 may be conformally formed.

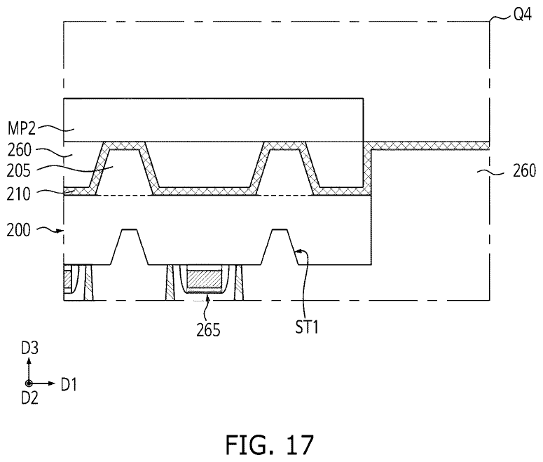

Referring to FIG. 17, a portion of the peripheral circuit insulating film 260 and a second mask pattern MP2 may be formed on the liner layer 210.

Specifically, an insulating material may be deposited on the liner layer 210. The insulating material may include, for example, a silicon oxide film deposited using a CVD tetraethylorthosilicate (TEOS) process, but example embodiments are not limited thereto. The insulating material may be deposited to completely cover the liner layer 210. By planarization of the deposited insulating material, the peripheral circuit insulating film 260 may be formed on the liner layer 210, and a portion of the liner layer 210 may be exposed. The upper surface of the peripheral circuit insulating film 260 may be disposed on the same plane as the upper surface of the liner layer 210.

The second mask pattern MP2 may be formed on the liner layer 210 and the peripheral circuit insulating film 260. The second mask pattern MP2 may overlap the first peripheral circuit substrate 200 in the third direction D3. The second mask pattern MP2 may expose a portion of the liner layer 210.

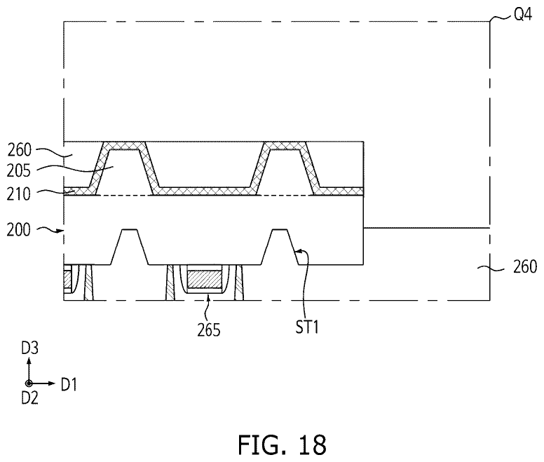

Referring to FIGS. 17 and 18, an etching process may be performed using the second mask pattern MP2 as an etching mask. Portions of the liner layer 210 and the peripheral circuit insulating film 260 exposed by the second mask pattern MP2 may be removed by the etching process. The second mask pattern MP2 may be removed.

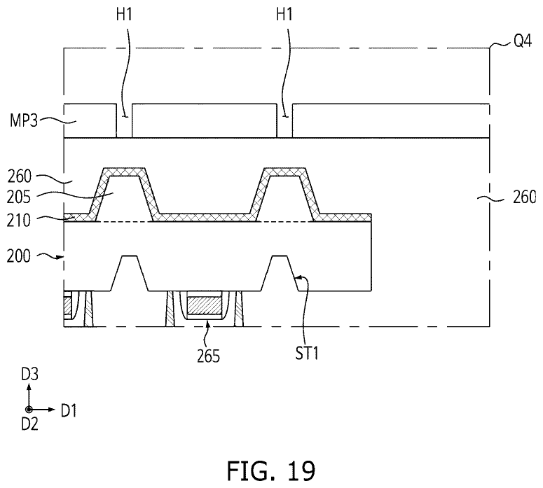

Referring to FIG. 19, the peripheral circuit insulating film 260 may be formed to cover the liner layer 210, and a third mask pattern MP3 may be formed on the peripheral circuit insulating film 260.

Specifically, an insulating material may be deposited on the peripheral circuit insulating film 260 and planarized. The insulating material may include, for example, silicon oxide, but example embodiments are not limited thereto. The third mask pattern MP3 may be formed on the peripheral circuit insulating film 260. The third mask pattern MP3 may include a mask hole H1. The mask hole H1 may expose a portion of the peripheral circuit insulating film 260. The mask hole H1 may overlap the protrusion 205 of the first peripheral circuit substrate 200 in the third direction D3.

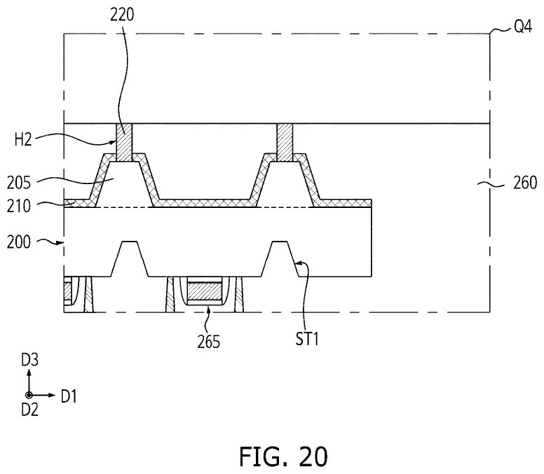

Referring to FIGS. 19 and 20, an etching process may be performed using the third mask pattern MP3 as an etching mask, and the pad contact 220 may be formed in the peripheral circuit insulating film 260.

Specifically, a portion of the peripheral circuit insulating film 260 exposed by the mask hole H1 may be removed, forming a contact hole H2. The contact hole H2 may expose the upper surface of the protrusion 205 and a portion of the liner layer 210. A metal material may be deposited inside the contact hole H2. The metal material may be formed using, for example, a chemical vapor deposition (CVD) method, a physical vapor deposition (PVD) method, or an atomic layer deposition (ALD) method. In some example embodiments, the metal material may fill the interior of the contact hole H2 and cover the upper surface of the peripheral circuit insulating film 260. The metal material may be planarized to form the pad contact 220 and expose the upper surface of the peripheral circuit insulating film 260.

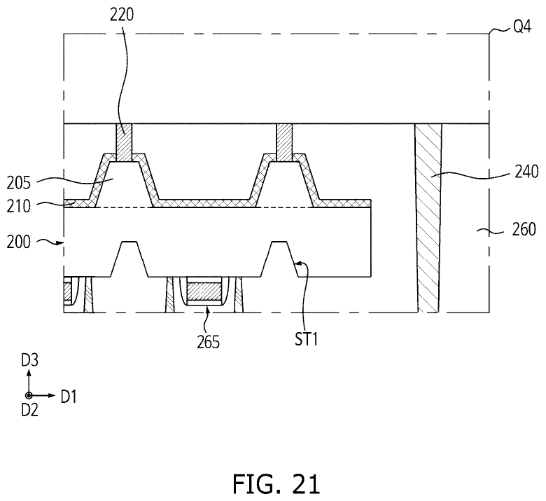

Referring to FIG. 21, the through via 240 may be formed in the peripheral circuit insulating film 260. Specifically, a mask pattern may be formed on the peripheral circuit insulating film 260, and a through via hole may be formed using the mask pattern. The through via 240 may be formed by filling the interior of the through via hole with a conductive material.

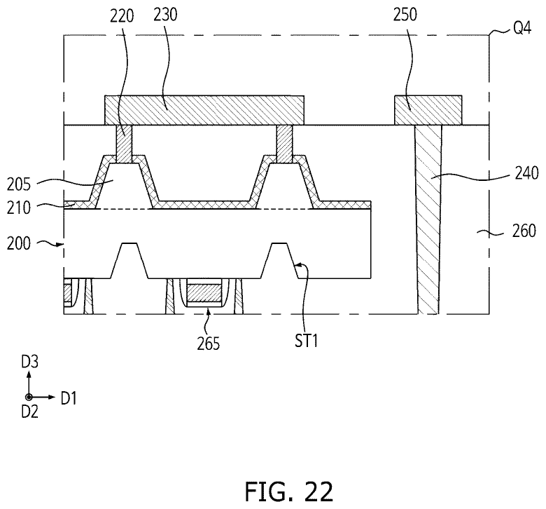

Referring to FIG. 22, the first pad 230 and the second pad 250 may be formed. Specifically, a metal material may be deposited on the upper surface of the peripheral circuit insulating film 260, an upper surface of the pad contact 220, and an upper surface of the through via 240. The metal material may be formed using, for example, a chemical vapor deposition (CVD) method, a physical vapor deposition (PVD) method, or an atomic layer deposition (ALD) method. The metal material may be patterned to form the first pad 230 and the second pad 250. The first pad 230 may be in contact with the upper surface of the pad contact 220, and the second pad 250 may be in contact with the upper surface of the through via 240.

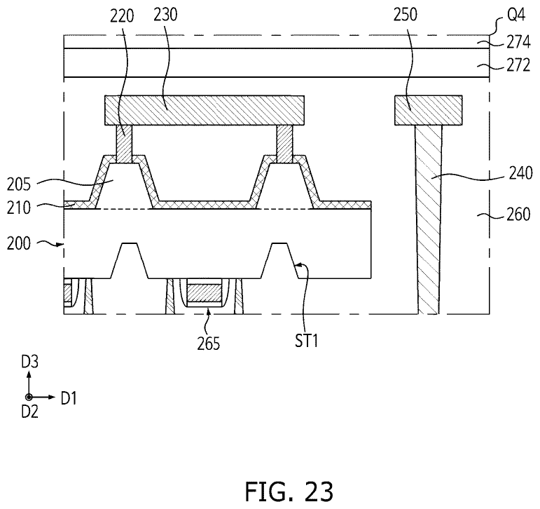

Referring to FIG. 23, by depositing an insulating material, the height of the peripheral circuit insulating film 260 may be increased and the first upper insulating film 272 and the second upper insulating film 274 may be sequentially stacked on the peripheral circuit insulating film 260.

Specifically, the insulating material may be deposited on the peripheral circuit insulating film 260 to cover an upper surface of the first pad 230 and an upper surface of the second pad 250. The insulating material may include, for example, TEOS. A portion of the peripheral circuit insulating film 260 may be removed by a planarization process to expose the upper surface of the first pad 230 and the upper surface of the second pad 250. A silicon oxide may be deposited on the peripheral circuit insulating film 260 to increase the height of the peripheral circuit insulating film 260 and cover the first pad 230 and the second pad 250. The first upper insulating film 272 and the second upper insulating film 274 may be formed on the upper surface of the peripheral circuit insulating film 260.

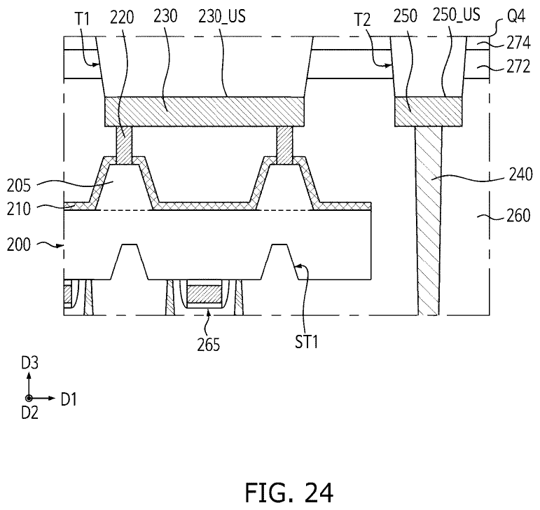

Referring to FIG. 24, the first trench T1 and the second trench T2 may be formed in the peripheral circuit insulating film 260, the first upper insulating film 272, and the second upper insulating film 274. The first trench T1 and the second trench T2 may be formed by a photolithography process.

The first trench T1 may expose the upper surface 230_US of the first pad 230. The bottom surface of the first trench T1 may be defined as the upper surface 230_US of the first pad 230. The width of the bottom surface of the first trench T1 in the first direction D1 may be the same as the width of the upper surface of the first pad 230 in the first direction D1. The side surface of the first pad 230 may be covered by the peripheral circuit insulating film 260.

The second trench T2 may expose the upper surface 250_US of the second pad 250. The bottom surface of the second trench T2 may be defined as the upper surface 250_US of the second pad 250. The width of the bottom surface of the second trench T2 in the first direction D1 may be the same as the width of the upper surface of the second pad 250 in the first direction D1. The side surface of the second pad 250 may be covered by the peripheral circuit insulating film 260.

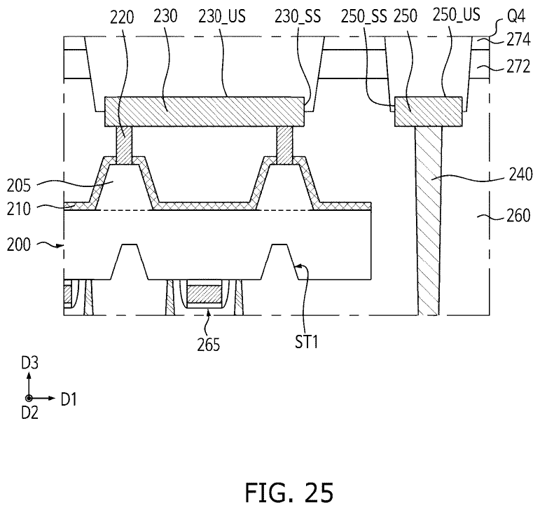

Referring to FIG. 25, a wet etching process may be performed on the first trench T1 and the second trench T2. A portion of the peripheral circuit insulating film 260 may be removed by the wet etching process, and the width of the first trench T1 may increase in the first direction D1. As a result, a portion of the side surface 230_SS of the first pad 230 may be exposed by the first trench T1. In addition, a portion of the peripheral circuit insulating film 260 may be removed by the wet etching process, and the width of the second trench T2 in the first direction D1 may increase. As a result, a portion of the side surface 250_SS of the second pad 250 may be exposed by the second trench T2.

In some example embodiments, a portion of the peripheral circuit insulating film 260 may be removed by the wet etching process, and the first upper insulating film 272 may not be removed. As a result, as illustrated in FIG. 8, the first width expansion region WER1 and the second width expansion region WER2 may be formed on the peripheral circuit insulating film 260.

In FIG. 13, although it is illustrated herein that the manufacturing process of the semiconductor memory device is performed with the peripheral circuit structure PERI being stacked on the cell structure CELL, example embodiments are not limited thereto. For example, the peripheral circuit structure PERI may be stacked on the cell structure CELL after the processes shown in FIGS. 14 to 25 are performed to form the peripheral circuit structure PERI.

FIG. 26 is an example block diagram provided to explain an electronic system according to some example embodiments.

Referring to FIG. 26, an electronic system 1000 may include a semiconductor memory device 1100 described above with reference to FIGS. 1 to 25 and a controller 1200 electrically connected to the semiconductor memory device 1100. The electronic system 1000 may be a storage device including one or a plurality of semiconductor memory devices 1100 or an electronic device including the storage device. For example, the electronic system 1000 may be a solid state drive device (SSD), a universal serial bus (USB), a computing system, a medical device, or a communication device, which may include one or the plurality of semiconductor memory devices 1100.

For example, the semiconductor memory device 1100 may be the NAND flash memory device described above with reference to FIGS. 1 to 25. The semiconductor memory device 1100 may include a first structure 1100F and a second structure 1100S on the first structure 1100F. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary according to various embodiments.

In some example embodiments, the upper transistors UT1 and UT2 may include a string select transistor, and the lower transistors LT1 and LT2 may include a ground select transistor. The gate lower lines LL1 and LL2 each may be gate electrodes of the lower transistors LT1 and LT2. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 extending from within the first structure 1100F and to the second structure 1100S. The bit lines BL may be electrically connected to the page buffer 1120 through second connection wires 1125 extending from within the first structure 1100F and to the second structure 1100S.

In the first structure 1100F, the decoder circuit 1110 and the page buffer 1120 may perform a control operation on at least one select memory cell transistor among the plurality of memory cell transistors MCT. The decoder circuit 1110 and the page buffer 1120 may be controlled by the logic circuit 1130. The semiconductor memory device 1100 may communicate with the controller 1200 through an input and output pad 1101 electrically connected to the logic circuit 1130. The input and output pad 1101 may be electrically connected to the logic circuit 1130 through an input and output connection wiring 1135 extending from within the first structure 1100F and to the second structure 1100S.

The controller 1200 may include a processor 1210, a NAND controller 1220, and a host interface 1230. According to some example embodiments, the electronic system 1000 may include the plurality of semiconductor memory devices 1100, and in this case, the controller 1200 may control the plurality of semiconductor memory devices 1100.

The processor 1210 may control the overall operation of the electronic system 1000 including the controller 1200. The processor 1210 may operate according to desired (and/or alternatively predetermined) firmware, and may control the NAND controller 1220 to access the semiconductor memory device 1100. The NAND controller 1220 may include a NAND interface (or controller interface) 1221 that processes communication with the semiconductor memory device 1100. A control command for controlling the semiconductor memory device 1100, data to be written in the memory cell transistors MCT of the semiconductor memory device 1100, data to be read from the memory cell transistors MCT of the semiconductor memory device 1100, etc. may be transmitted through the NAND interface 1221. The host interface 1230 may provide a communication function between the electronic system 1000 and an external host. Upon receiving a control command from the external host through the host interface 1230, the processor 1210 may control the semiconductor memory device 1100 in response to the control command.

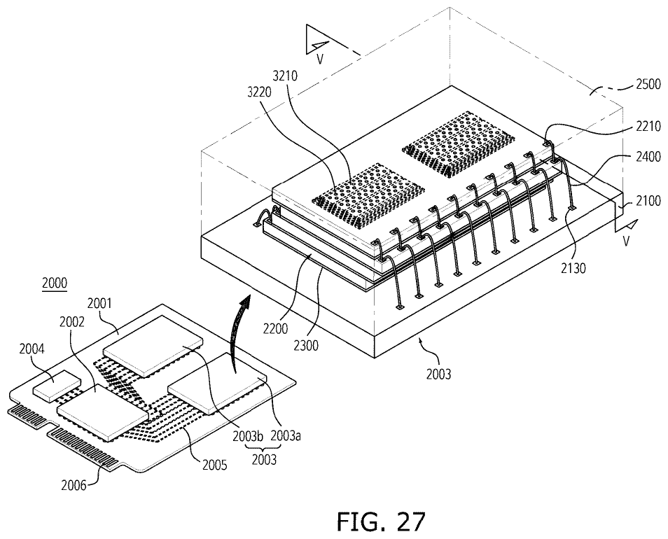

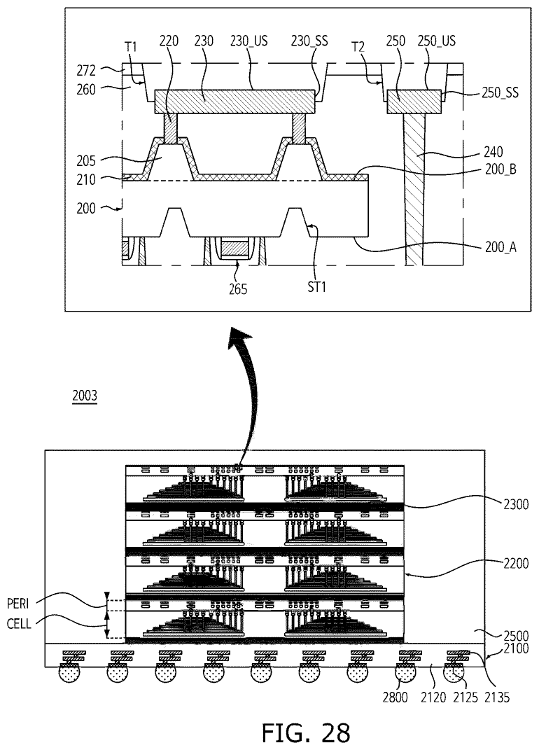

FIG. 27 is an example perspective view provided to explain an electronic system according to some example embodiments. FIG. 28 is a schematic cross-sectional view taken along line V-V of FIG. 27.

Referring to FIGS. 27 and 28, an electronic system 2000 may include a main substrate 2001, a main controller 2002 mounted on the main substrate 2001, one or more semiconductor packages 2003, and a DRAM 2004. The semiconductor package 2003 and the DRAM 2004 may be connected to the main controller 2002 by wiring patterns 2005 formed on the main substrate 2001.

The main substrate 2001 may include a connector 2006 including a plurality of pins coupled to the external host. The number and arrangement of the plurality of pins in the connector 2006 may vary depending on a communication interface between the electronic system 2000 and the external host. In some example embodiments, the electronic system 2000 may communicate with the external host according to any one of interfaces such as Universal Serial Bus (USB), Peripheral Component Interconnect Express (PCI-Express), Serial Advanced Technology Attachment (SATA), and M-Phy for Universal Flash Storage (UFS). In some example embodiments, the electronic system 2000 may be operated by the power supplied from the external host through the connector 2006. The electronic system 2000 may further include a power management integrated circuit (PMIC) that distributes the power supplied from the external host to the main controller 2002 and the semiconductor package 2003.

The main controller 2002 may record data in the semiconductor package 2003 or read data from the semiconductor package 2003, and may improve the operation speed of the electronic system 2000.

The DRAM 2004 may be a buffer memory to alleviate the speed difference between the external host and the semiconductor package 2003 that is a data storage space. The DRAM 2004 included in the electronic system 2000 may also operate as a kind of cache memory, and may also provide a space for temporarily storing data in a control operation for the semiconductor package 2003. If the electronic system 2000 includes the DRAM 2004, in addition to the NAND controller for controlling the semiconductor package 2003, the main controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input and output pad 2210. The input and output pad 2210 may correspond to the input and output pad 1101 of FIG. 26. Each of the semiconductor chips 2200 may include metal lines 3210 and channel structures 3220. Each of the semiconductor chips 2200 may include the semiconductor memory device described above with reference to FIGS. 1 to 25.

In some example embodiments, the connection structure 2400 may be a bonding wire electrically connecting the input and output pad 2210 to the package upper pads 2130. Therefore, in each of the first and second semiconductor packages 2003a and 2003b, the semiconductor chips 2200 may be electrically connected to each other with the bonding wire method, and may be electrically connected to the package upper pads 2130 of the package substrate 2100. In some example embodiments, in each of the first and second semiconductor packages 2003a and 2003b, the semiconductor chips 2200 may be electrically connected to each other through a connection structure including Through Silicon Via (TSV) instead of a bonding wire type connection structure 2400.

In some example embodiments, the main controller 2002 and the semiconductor chips 2200 may be included in one package. In some example embodiments, the main controller 2002 and the semiconductor chips 2200 may be mounted on a separate interposer substrate different from the main substrate 2001, and the main controller 2002 and the semiconductor chips 2200 may be connected to each other through wiring formed on the interposer substrate.

In some example embodiments, the package substrate 2100 may be a printed circuit board. The package substrate 2100 may include a package substrate body portion 2120, the package upper pads 2130 disposed on an upper surface of the package substrate body portion 2120, lower pads 2125 disposed on a lower surface of the package substrate body portion 2120 or exposed through the lower surface, and internal wires 2135 electrically connecting the package upper pads 2130 and the lower pads 2125 inside the package substrate body portion 2120. The package upper pads 2130 may be electrically connected to the connection structures 2400. The lower pads 2125 may be connected to the wiring patterns 2005 of the main substrate 2001 of the electronic system 2000 through conductive connections 2800, as illustrated in FIG. 20.

In an electronic system according to some example embodiments, each of the semiconductor chips 2200 may include the semiconductor memory device described above with reference to FIGS. 1 to 18. For example, each of the semiconductor chips 2200 may include the cell structure CELL and the peripheral circuit structure PERI stacked on the cell structure CELL. For example, the peripheral circuit structure PERI may include the first peripheral circuit substrate 200, the liner layer 210, the pad contact 220, the first pad 230, etc., which are described above with reference to FIGS. 1 to 25. In addition, for example, the cell structure CELL may include the cell substrate 100, the mold structure MS, the channel structure CH, etc., which are described above using FIGS. 1 to 25.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although certain example embodiments of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the example embodiments described above are illustrative and non-limiting in all respects.

1. A semiconductor memory device, comprising:
a cell structure; and
a peripheral circuit structure on the cell structure,
wherein the peripheral circuit structure comprises
a peripheral circuit substrate comprising
a first surface,
a second surface opposite to the first surface, and
a protrusion protruding from the second surface,
a peripheral circuit transistor on the first surface,
a liner layer extending along the second surface, and the liner layer on an upper surface and side surfaces of the protrusion,
a peripheral circuit insulating film on the liner layer,
a first pad on the peripheral circuit insulating film, and
a pad contact in the peripheral circuit insulating film and connected to the first pad.

2. The semiconductor memory device according to claim 1, wherein
the peripheral circuit structure further comprises
a first trench in the peripheral circuit insulating film, and
the first trench exposing an upper surface and at least a portion of a side surface of the first pad.

3. The semiconductor memory device according to claim 1, wherein the pad contact is on the upper surface of the protrusion.

4. The semiconductor memory device according to claim 1, wherein the pad contact penetrates the liner layer and is in contact with the peripheral circuit substrate.

5. The semiconductor memory device according to claim 1, wherein
the peripheral circuit structure further comprises
a device isolation trench in the peripheral circuit substrate and on one side of the peripheral circuit transistor, and
the device isolation trench overlaps the protrusion in a direction perpendicular to the second surface.

6. The semiconductor memory device according to claim 1, wherein
the peripheral circuit structure further comprises
a through via penetrating the peripheral circuit insulating film, and
a second pad on the through via, and
the second pad is at a same level as a level of the first pad.

7. The semiconductor memory device according to claim 6, wherein
the peripheral circuit structure further comprises
a second trench on an upper surface of the peripheral circuit insulating film, and
the second trench exposing an upper surface and at least a portion of a side surface of the second pad.

8. The semiconductor memory device according to claim 6, wherein a width of the through via decreases as a distance from the second pad increases.

9. The semiconductor memory device according to claim 1, wherein
the cell structure further comprises
a cell substrate
a plurality of gate electrodes stacked to be spaced apart from each other on the cell substrate; and
a channel structure penetrating the plurality of gate electrodes.

10. The semiconductor memory device according to claim 1, wherein
the peripheral circuit structure further comprises
a first trench on the peripheral circuit insulating film,
the first trench comprising a width expansion region expanding in a direction parallel to the second surface, and
the width expansion region exposing at least a portion of a side surface of the first pad.

11. A semiconductor memory device, comprising:
a channel structure;
a cell interlayer insulating film covering the channel structure;
a cell structure comprising a first bonding pad on the cell interlayer insulating film; and
a peripheral circuit structure on the cell structure,
wherein the peripheral circuit structure comprises
a peripheral circuit substrate comprising a first surface and a second surface opposite to the first surface,
a peripheral circuit transistor on the first surface,
a second bonding pad between the peripheral circuit substrate and the cell structure, the second bonding pad coupled to the first bonding pad,
a liner layer on the second surface,
a peripheral circuit insulating film on the liner layer,
a first pad on the peripheral circuit insulating film,
a pad contact in the peripheral circuit insulating film and connected to the first pad, and
a first trench on an upper surface of the peripheral circuit insulating film, the first trench exposing at least a portion of the first pad.

12. The semiconductor memory device according to claim 11, wherein at least a portion of the liner layer is extending in a direction parallel to the second surface.

13. The semiconductor memory device according to claim 11, wherein a width of a bottom surface of the first trench in a direction parallel to the second surface is greater than a width of the first pad in the direction parallel to the second surface.

14. The semiconductor memory device according to claim 11, wherein the pad contact is in contact with the liner layer.

15. The semiconductor memory device according to claim 11, wherein
the peripheral circuit substrate further comprises a protrusion protruding from the second surface, and
the liner layer is on an upper surface and side surfaces of the protrusion.

16. The semiconductor memory device according to claim 11, wherein
the peripheral circuit structure further comprises a filling layer filling the first trench, and
the filling layer is in contact with an upper surface and at least a portion of a side surface of the first pad.

17. The semiconductor memory device according to claim 11, wherein
the peripheral circuit structure further comprises
a through via spaced apart from the peripheral circuit substrate, the through via penetrating the peripheral circuit insulating film, and
a second pad on the through via, the second pad at a same level as a level of the first pad.

18. The semiconductor memory device according to claim 11, wherein the peripheral circuit structure further comprises a peripheral circuit wiring structure connecting the second bonding pad and the peripheral circuit transistor.

19. The semiconductor memory device according to claim 11, wherein
the cell structure further comprises a connection via on a connection area and in the cell interlayer insulating film, and
the connection via is electrically connected to the peripheral circuit transistor.

20. An electronic system, comprising:
a main substrate;
a semiconductor memory device comprising a cell structure on the main substrate and a peripheral circuit structure stacked on the cell structure; and
a controller on the main substrate and electrically connected to the semiconductor memory device,
wherein the cell structure comprises
a cell substrate,
a plurality of gate electrodes stacked to be spaced apart from each other on the cell substrate,
a channel structure penetrating the plurality of gate electrodes, and
a first bonding pad on the channel structure, and
the peripheral circuit structure comprises,
a peripheral circuit substrate comprising
a first surface,
a second surface opposite to the first surface, and
a protrusion protruding from the second surface,
a peripheral circuit transistor on the first surface,
a second bonding pad between the peripheral circuit transistor and the channel structure, the second bonding pad coupled to the first bonding pad,
a liner layer extending along the second surface and an upper surface and side surfaces of the protrusion,
a peripheral circuit insulating film on the liner layer,
a pad on the peripheral circuit insulating film,
a pad contact in the peripheral circuit insulating film and connected to the pad, and
a trench on an upper surface of the peripheral circuit insulating film and exposing an upper surface and at least a portion of a side surface of the pad.
